(19) United States
(12) Patent Application Publication
(10) Pub. No.: US 2016/0079946 A1
(43) Pub. Date: Mar. 17, 2016

(54) MULTI-BAND LOW NOISE AMPLIFIER WITH A SHARED DEGENERATION INDUCTOR

(71) Applicant: QUALCOMM Incorporated, San Diego, CA (US)

(72) Inventors: Gireesh Rajendran, Bangalore (IN); Rakesh Kumar, Ghazipur (IN); Manohar Seetharam, Bangalore (IN)

(21) Appl. No.: 14/485,368

(22) Filed: Sep. 12, 2014

(51) Int. Cl. H03G 3/30

(52) U.S. Cl. CPC H03G 3/3042

(57) ABSTRACT

An apparatus includes a first transistor configured to amplify first signal components within a first frequency band of a radio frequency signal, a second transistor configured to amplify second signal components within a second frequency band of the radio frequency signal, and a third transistor configured to amplify third signal components within a third frequency band of the radio frequency signal. The apparatus also includes a degeneration inductor having a first tapping point, a second tapping point, and a third tapping point. The first tapping point is coupled to the first transistor, the second tapping point is coupled to the second transistor, and the third tapping point is coupled to the third transistor.

### I. FIELD

The present disclosure is generally related to a multi-band low noise amplifier with a shared degeneration inductor.

### II. DESCRIPTION OF RELATED ART

Advances in technology have resulted in smaller and more powerful computing devices. For example, there currently exist a variety of portable personal computing devices, including wireless computing devices, such as portable wireless telephones, personal digital assistants (PDAs), and paging devices that are small, lightweight, and easily carried by users. More specifically, portable wireless telephones, such as cellular telephones and Internet protocol (IP) telephones, can communicate voice and data packets over wireless networks. Further, many such wireless telephones include other types of devices that are incorporated therein. For example, a wireless telephone can also include a digital still camera, a digital video camera, a digital recorder, and an audio file player. Also, such wireless telephones can process executable instructions, including software applications, such as a web browser application, that can be used to access the Internet. As such, these wireless telephones can include significant computing capabilities.

Wireless devices may include a multi-band low noise amplifier having multiple branches. Each branch may include a transistor and a degeneration inductor, and each branch may operate within a distinct frequency band. As a non-limiting example, a first branch may operate in a low frequency band (e.g., a 900 Megahertz (MHz) frequency band), a second branch may operate in a mid-range frequency band (e.g., an 1800 MHz frequency band), and a third branch may operate in a high frequency band (e.g., a 2.6 Gigahertz (GHz) frequency band). The first branch may use a relatively large degeneration inductor (e.g., an inductor having a relatively large number of turns) to tune for linearity in the low frequency band, the second branch may use a “mid-size” degeneration inductor to tune for linearity in the mid-range frequency band, and the third branch may use a relatively small degeneration inductor to tune for linearity in the high frequency band. Having an independent degeneration inductor for each branch may consume a relatively large amount of die area.

### III. BRIEF DESCRIPTION OF THE DRAWINGS

FIG. 1 shows a wireless device communicating with a wireless system;

FIG. 2 shows a block diagram of the wireless device in FIG. 1;

FIG. 3 is a diagram that depicts an exemplary embodiment of a multi-band low noise amplifier with a shared degeneration inductor;

FIG. 4 is a diagram that depicts an exemplary embodiment of additional components of the multi-band low noise amplifier of FIG. 3;

FIG. 5 is a diagram that depicts another exemplary embodiment of a multi-band low noise amplifier with a shared degeneration inductor; and

FIG. 6 is a flowchart that illustrates an exemplary embodiment of a method of operating a multi-band low noise amplifier with a shared degeneration inductor.

### IV. DETAILED DESCRIPTION

The detailed description set forth below is intended as a description of exemplary designs of the present disclosure and is not intended to represent the only designs in which the present disclosure can be practiced. The term “exemplary” is used herein to mean “serving as an example, instance, or illustration.” Any design described herein as “exemplary” is not necessarily to be construed as preferred or advantageous over other designs. The detailed description includes specific details for the purpose of providing a thorough understanding of the exemplary designs of the present disclosure. It will be apparent to those skilled in the art that the exemplary designs described herein may be practiced without these specific details. In some instances, well-known structures and devices are shown in block diagram form in order to avoid obscuring the novelty of the exemplary designs presented herein.

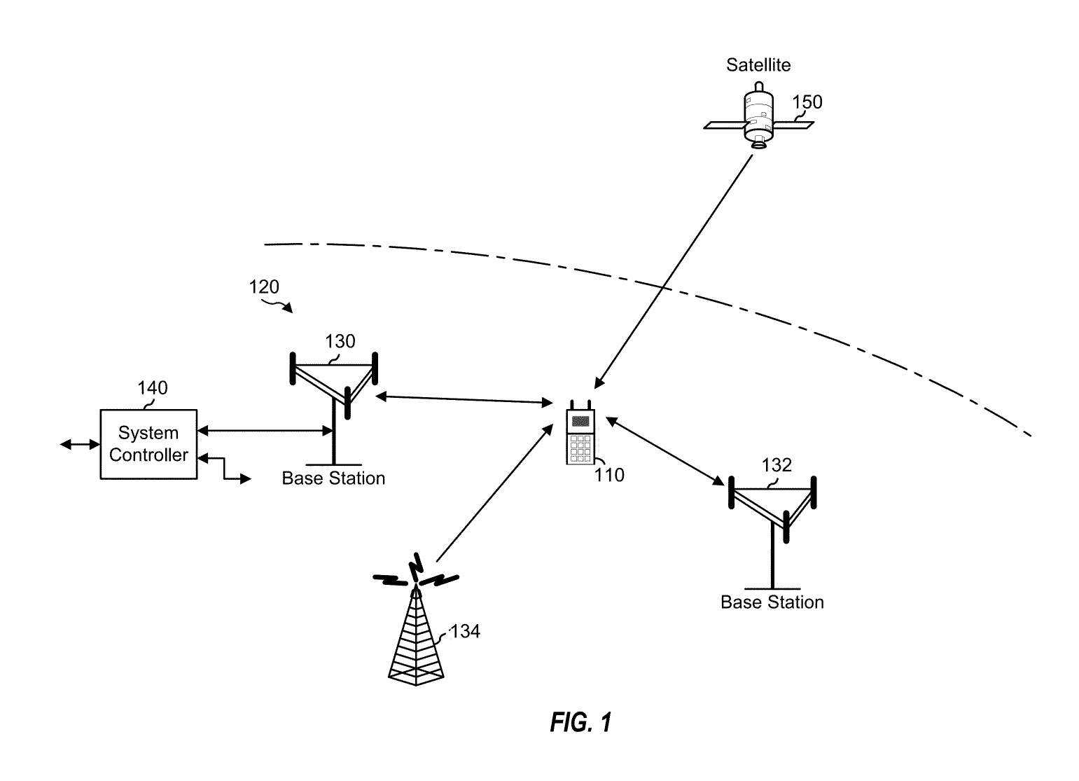

FIG. 1 shows a wireless device 110 communicating with a wireless communication system 120. The wireless communication system 120 may be a Long Term Evolution (LTE) system, a Code Division Multiple Access (CDMA) system, a Global System for Mobile Communications (GSM) system, a wireless local area network (WLAN) system, or some other wireless system. A CDMA system may implement Wideband CDMA (WCDMA), CDMA 1×, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless system may include any number of base stations and any set of network entities.

The wireless device 110 may also be referred to as a user equipment (UE), a mobile station, a terminal, an access terminal, a subscriber unit, a station, etc. The wireless device 110 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth device, etc. The wireless device 110 may communicate with wireless system 120. The wireless device 110 may also receive signals from broadcast stations (e.g., a broadcast station 134), signals from satellites (e.g., a satellite 150) in one or more global navigation satellite systems (GNSS), etc. The wireless device 110 may support one or more radio technologies for wireless communication such as LTE, WCDMA, CDMA 1×, EVDO, TD-SCDMA, GSM, 802.11, etc.

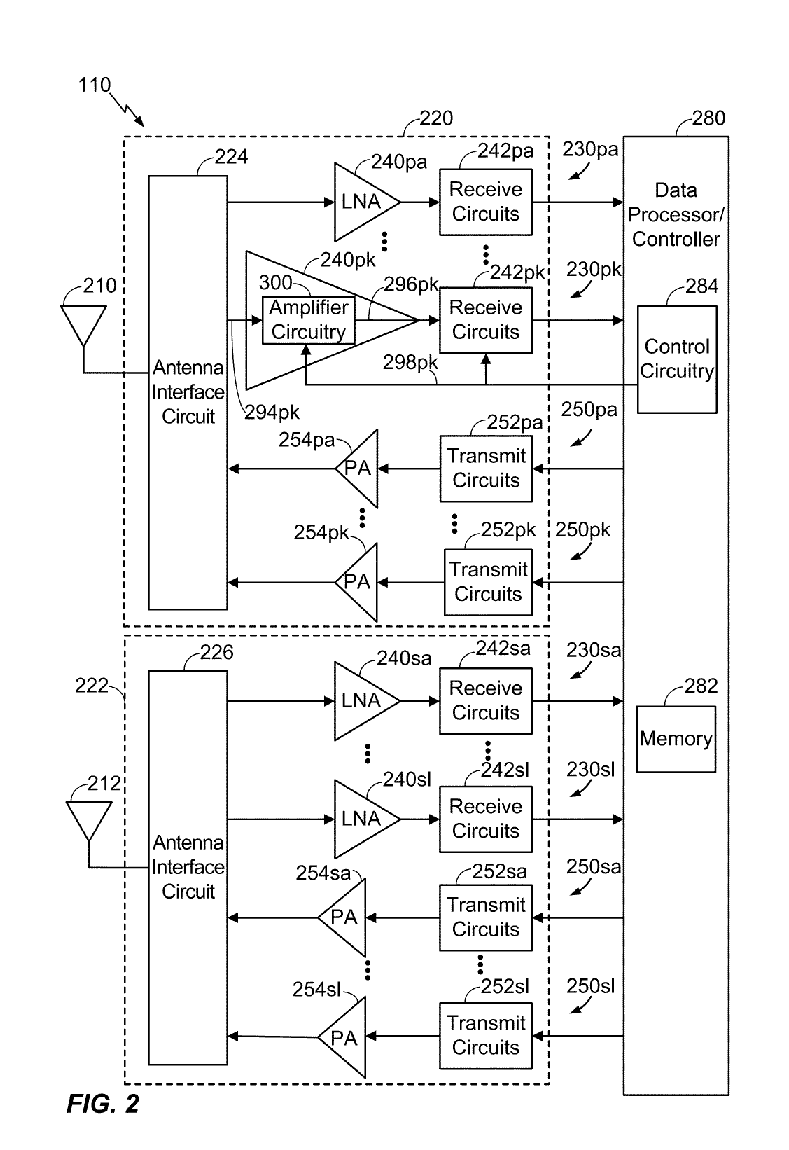

FIG. 2 shows a block diagram of an exemplary design of the wireless device 110 in FIG. 1. In this exemplary design, the wireless device 110 includes a transceiver 220 coupled to a primary antenna 210, a transceiver 222 coupled to a secondary antenna 212, and a data processor/controller 280. The transceiver 220 includes multiple (K) receivers 230pa to 230pk and multiple (K) transmitters 250pa to 250pk to support multiple frequency bands, multiple radio technologies, carrier aggregation, etc. The transceiver 222 includes multiple (L) receivers 230sa to 230sl and multiple (L) transmitters 250sa to 250sl to support multiple frequency bands, multiple radio technologies, carrier aggregation, receive diversity, multiple-input multiple-output (MIMO) transmission from multiple transmit antennas to multiple receive antennas, etc.

In the exemplary design shown in FIG. 2, each receiver 230pa to 230pk and 230sa to 230sl includes a multi-band LNA 240pa to 240pk and 240sa to 240sl and a receive circuit 242pa to 242pk and 242sa to 242sl, respectively. For data reception, the primary antenna 210 receives signals from base stations and/or other transmitter stations and provides a received RF signal, which is routed through an antenna interface circuit 224 and presented as an input RF signal 294pk to a selected receiver (e.g., the receiver 230pk). In a similar manner, the secondary antenna 212 receives signals from base stations and/or other transmitter stations and provides a received RF signal, which is routed through an antenna interface circuit 226 and presented an input RF signal to a selected receiver.

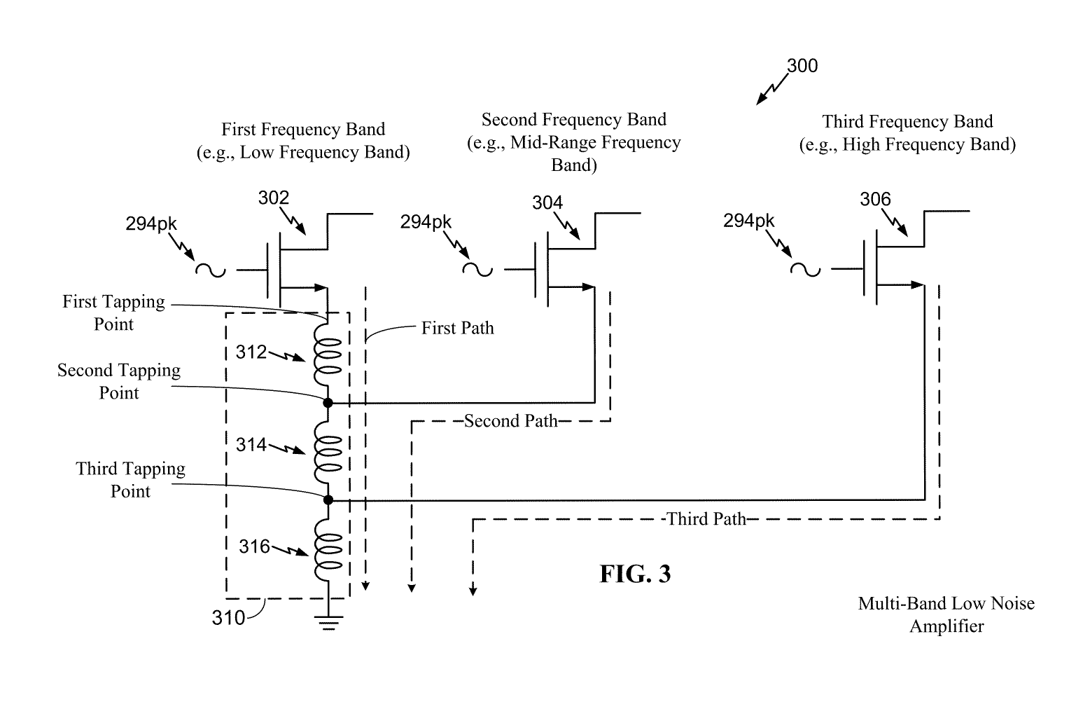

In an exemplary embodiment, the input RF signal 294pk may be a multi-band signal having first signal components in a first frequency band (e.g., a 900 Megahertz (MHz) frequency band), second signal components in a second frequency band (e.g., an 1800 MHz frequency band), and/or third signal components in a third frequency band (e.g., a 2.6 Gigahertz (GHz) frequency band). The antenna interface circuit 224 may include switches, duplexers, transmit filters, receive filters, matching circuits, etc. The description below assumes that the receiver 230pk is the selected receiver. Within the receiver 230pk, an LNA 240pk amplifies the input RF signal 294pk and provides an output RF signal 296pk. For example, the LNA 240pk may include amplification circuitry 300, as further described with respect to FIG. 3, to amplify the input RF signal 294pk.

The receive circuits 242pk may downconvert the output RF signal 296pk from RF to baseband, amplify and filter the downconverted signal, and provide an analog input signal to the data processor/controller 280. The receive circuits 242pk may include mixers, filters, amplifiers, matching circuits, an oscillator, a local oscillator (LO) generator, a phase locked loop (PLL), etc. Each remaining receiver 230pa, 230sa, 230sl in the transceivers 220, 222 may operate in similar manner as the receiver 230pk.

In the exemplary design shown in FIG. 2, each transmitter 250pa to 250pk and 250sa to 250sl includes a transmit circuit 252pa to 252pk and 252sa to 252sl and a power amplifier (PA) 254pa to 254pk and 254sa to 254sl, respectively. For data transmission, the data processor/controller 280 processes (e.g., encodes and modulates) data to be transmitted and provides an analog output signal to a selected transmitter. The description below assumes that the transmitter 250pa is the selected transmitter. Within transmitter 250pa, the transmit circuits 252pa amplify, filter, and upconvert the analog output signal from baseband to RF and provide a modulated RF signal. The transmit circuits 252pa may include amplifiers, filters, mixers, matching circuits, an oscillator, an LO generator, a PLL, etc. A PA 254pa receives and amplifies the modulated RF signal and provides a transmit RF signal having the proper output power level. The transmit RF signal is routed through the antenna interface circuit 224 and transmitted via the primary antenna 210. Each remaining transmitter 250pk, 250sa, 25sl in the transceivers 220, 222 may operate in similar manner as the transmitter 250pa.

FIG. 2 shows an exemplary design of receivers 230pa to 230pk and 230sa to 230sl and transmitters 250pa to 250pk and 250sa to 250sl. A receiver and a transmitter may also include other circuits not shown in FIG. 2, such as filters, matching circuits, etc. All or a portion of the transceivers 220 and 222 may be implemented on one or more analog integrated circuits (ICs), RF ICs (RFICs), mixed-signal ICs, etc. For example, LNAs 240pa to 240pk and 240sa to 240sl and receive circuits 242pa to 242pk and 242sa to 242sl may be implemented on one module, which may be an RFIC, etc. The circuits in the transceivers 220 and 222 may also be implemented in other manners.

In an exemplary embodiment, one or more of the multi-band LNAs 240pa to 240pk and 240sa to 240sl may receive a control signal (e.g., control signal 298pk) from control circuitry 284 in the data processor/controller 280 to operate the corresponding multi-band LNA (e.g., the LNA 240pk) in the first frequency band, the second frequency band, or the third frequency band.

The data processor/controller 280 may perform various functions for wireless device 110. For example, the data processor/controller 280 may perform processing for data being received via the receivers 230pa to 230pk and 230sa to 230sl and data being transmitted via the transmitters 250pa to 250pk and 250sa to 250sl. The data processor/controller 280 may control the operation of the various circuits within transceivers 220 and 222. For example, the data processor/controller 280 may include the control circuitry 284 to operate a multi-band LNA (e.g., the LNA 240pk) in the first frequency band, the second frequency band, or the third frequency band. A memory 282 may store program codes and data for data processor/controller 280. The data processor/controller 280 may be implemented on one or more application specific integrated circuits (ASICs) and/or other ICs.

Wireless device 110 may support multiple band groups, multiple radio technologies, and/or multiple antennas. Wireless device 110 may include a number of LNAs to support reception via the multiple band groups, multiple radio technologies, and/or multiple antennas.

Referring to FIG. 3, a diagram of an exemplary embodiment of a multi-band low noise amplifier having a shared degeneration inductor is shown. For example, FIG. 3 illustrates an exemplary embodiment of the amplification circuitry 300 in the LNA 240pk of FIG. 2, and the amplification circuitry 300 may correspond to a multi-band low noise amplifier.

The amplification circuitry 300 includes a first transistor 302 (e.g., a first LNA branch), a second transistor 304 (e.g., a second LNA branch), and a third transistor 306 (e.g., a third LNA branch). In an exemplary embodiment, each transistor 302-306 is an n-type metal oxide semiconductor (NMOS) transistor. Each LNA branch may be tuned to a different frequency band. The first LNA branch may be tuned to the first frequency band (e.g., the “low” frequency band or the 900 MHz frequency band), the second LNA branch may be tuned to the second frequency band (e.g., the “mid-range” frequency band or the 1800 MHz frequency band), and the third LNA branch may be tuned to the third frequency band (e.g., the “high” frequency band or the 2.6 GHz frequency band). For example, a center frequency of the third frequency band (e.g., the 2.6 GHz frequency band) may be greater than a center frequency of the second frequency band (e.g., the 1800 MHz frequency band), and the center frequency of the second frequency band may be greater than a center frequency of the first frequency band (e.g., the 900 MHz frequency band).

A gate of the first transistor 302 may be coupled to receive the input RF signal 294pk from a first input matching network (not shown), a gate of the second transistor 304 may be coupled to receive the input RF signal 294pk from a second input matching network (not shown), and a gate of the third transistor 306 may be coupled to receive the input RF signal 294pk from a third input matching network (not shown). As described below, each transistor 302-306 may operate as an amplification stage for signal components of the input RF signal 294pk. For example, the first transistor 302 may be configured to amplify first signal components of the input RF signal 294pk within the first frequency band, the second transistor 304 may be configured to amplify second signal components of the input RF signal 294pk within the second frequency band, and the third transistor 306 may be configured to amplify third signal components of the input RF signal 294pk within the third frequency band.

The amplification circuitry 300 may also include a “shared” degeneration inductor 310. The shared degeneration inductor 310 may be comprised of a plurality of serially coupled inductors 312-316. For example, the shared degeneration inductor 310 may include a first degeneration inductor 312 having a first inductance, a second degeneration inductor 314 having a second inductance, and a third degeneration inductor 316 having a third inductance. A first terminal of the third degeneration inductor 316 may be coupled to ground, and a second terminal of the third degeneration inductor 316 may be coupled to a first terminal of the second degeneration inductor 314. A second terminal of the second degeneration inductor 314 may be coupled to a first terminal of the first degeneration inductor 312, and a second terminal of the first degeneration inductor 312 may be coupled to the first transistor 302. Although illustrated as independent inductors, each degeneration inductor 312-316 may correspond to portions of a single degeneration inductor (e.g., the shared degeneration inductor 310) that are separated by “tapping points.”

Sources of the transistors 302-306 may be coupled to different tapping points of the shared degeneration inductor 310 such that each transistor 302-306 has a different degeneration inductance. To illustrate, a source of the first transistor 302 may be coupled to a first tapping point of the shared degeneration inductor 310 such that the degeneration inductance of the first transistor 302 is equal to the sum of the first inductance, the second inductance, and the third inductance. For example, the first tapping point may correspond to the second terminal of the first degeneration inductor 312. Thus, the first transistor 302, the first degeneration inductor 312, the second degeneration inductor 314, and the third degeneration inductor 316 may be included in a first path of the amplification circuitry 300. In an exemplary embodiment, the degeneration inductance of the first transistor 302 may enhance input matching (S11) between the antenna interface circuit 224 of FIG. 2 and the amplification circuitry 300 for first signal components within the first frequency band.

A source of the second transistor 304 may be coupled to a second tapping point of the shared degeneration inductor 310 such that the degeneration inductance of the second transistor 304 is equal to the sum of the second inductance and the third inductance. For example, the second tapping point may correspond to the second terminal of the second degeneration inductor 314. Thus, the second transistor 304, the second degeneration inductor 304, and the third degeneration inductor 316 may be included in a second path of the amplification circuitry 300. In an exemplary embodiment, the degeneration inductance of the second transistor 304 may enhance input matching (S11) between the antenna interface circuit 224 of FIG. 2 and the amplification circuitry 300 for second signal components within the second frequency band.

A source of the third transistor 306 may be coupled to a third tapping of the shared degeneration inductor 310 such that the degeneration inductance of the third transistor 306 is equal to the third inductance. For example, the third tapping point may correspond to the second terminal of the third degeneration inductor 316. Thus, the third transistor 306 and the third degeneration inductor 316 may be included in a third path of the amplification circuitry 300. In an exemplary embodiment, the degeneration inductance of the third transistor 302 may enhance input matching (S11) between the antenna interface circuit 224 of FIG. 2 and the amplification circuitry 300 for third signal components within the third frequency band.

The shared degeneration inductor 310 may include a first number of turns between the first tapping point and ground. For example, the first number of turns may be equal to the sum of the turns of the first degeneration inductor 312, the turns of the second degeneration inductor 314, and the turns of the third degeneration inductor 316. The shared degeneration inductor 310 may include a second number of turns between the second tapping point and ground. For example, the second number of turns may be equal to the sum of the turns of the second degeneration inductor 314 and the turns of the third degeneration inductor 316. The shared degeneration inductor 310 may include a third number of turns between the third tapping point and ground. For example, the third number of turns may be equal to the turns of the third degeneration inductor 316. Thus, the turns associated with second degeneration inductor 314 and the third degeneration inductor 316 may be “shared” with the first degeneration inductor 312 to generate the degeneration inductance of the first transistor 302. In a similar manner, turns of the third degeneration inductor 316 may be shared with the second degeneration inductor 314 to generate the degeneration inductance of the second transistor 304.

The amplification circuitry 300 of FIG. 3 (e.g., the multi-band LNA) may reduce die area consumption by coupling each transistor 302-306 (e.g., each LNA branch) to different tapping points of the shared degeneration inductor 310 as opposed to coupling an independent degeneration inductor to each branch. For example, the first transistor 302 may use “turns” of the second degeneration inductor 314 and the third degeneration inductor 316 to generate a relatively large degeneration inductance rather than using an independent degeneration inductor coupled to the source of the first transistor 302. Using the second degeneration inductor 314 reduces die area as compared to using an independent inductor coupled to the source of the first transistor 302. In a similar manner, the second transistor 304 may use turns of the third degeneration inductor 316 to generate a “mid-range” inductance to reduce the die area that would otherwise be necessary if an independent inductor was coupled to the source of the second transistor 304.

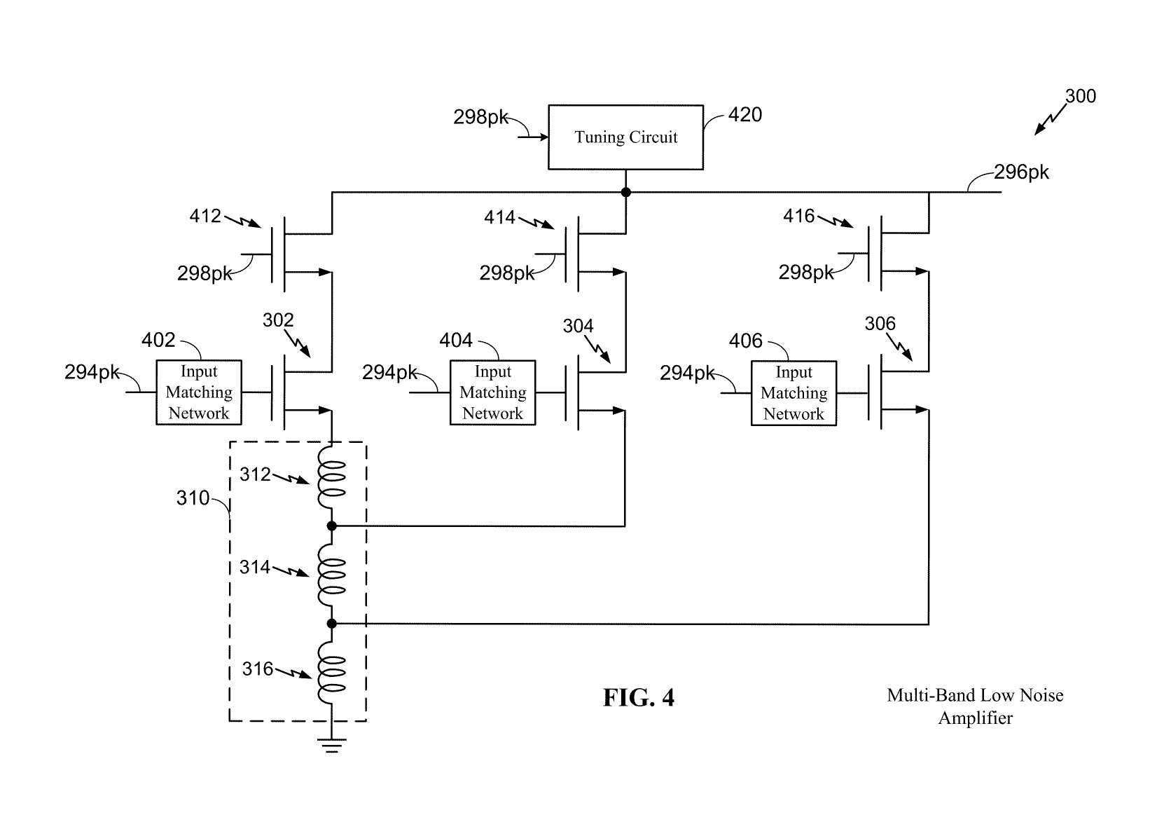

Referring to FIG. 4, a diagram of an exemplary embodiment of additional components of the amplification circuitry 300 is shown. The amplification circuitry 300 may be included in the LNA 240pk of FIG. 2.

A first input matching network 402 may be coupled to the gate of the first transistor 302, a second input matching network 404 may be coupled to the gate of the second transistor 304, and a third input matching network 406 may be coupled to the gate of the third transistor 306. The gate of the first transistor 302 may be coupled to receive the input RF signal 294pk from the first input matching network 402, the gate of the second transistor 304 may be coupled to receive the input RF signal 294pk from the second input matching network 404, and the gate of the third transistor 306 may be coupled to receive the input RF signal 294pk from a third input matching network 406.

Each input matching network 402-406 may be an inductive-capacitive (LC) network that is tuned to provide input matching between the amplification circuitry 300 and the antenna interface circuit 224 of FIG. 2 for different frequency bands. To illustrate, the first input matching network 402 and the degeneration inductance of the first transistor 302 (e.g., the sum of the first inductance of the first degeneration inductor 312, the second inductance of the second degeneration inductor 314, and the third inductance of the third degeneration inductor 316) may enhance input matching (S11) between the antenna interface circuit 224 and the amplification circuitry 300 for the first signal components within the first frequency band. The second input matching network 404 and the degeneration inductance of the second transistor 304 (e.g., the sum of the second inductance of the second degeneration inductor 314 and the third inductance of the third degeneration inductor 316) may enhance input matching (S11) between the antenna interface circuit 224 and the amplification circuitry 300 for the second signal components within the second frequency band. The third input matching network 406 and the degeneration inductance of the third transistor 306 (e.g., the third inductance of the third generation inductor 316) may enhance input matching (S11) between the antenna interface circuit 224 and the amplification circuitry 300 for the third signal components within the third frequency band.

A source of a first selection transistor 412 may be coupled to the drain of the first transistor 302, a source of a second selection transistor 414 may be coupled to the drain of the second transistor 304, and a source of a third selection transistor 416 may be coupled to the drain of the third transistor 306. In an exemplary embodiment, the selection transistors 412-416 may be NMOS transistors.

The control signal 298pk of FIG. 2 may be provided to gates of each selection transistor 412-416. The control signal 298pk may be a multi-bit signal configured to activate the first selection transistor 412, the second selection transistor 414, or the third selection transistor 416. For example, a first bit of the control signal 298pk may be provided to a gate of the first selection transistor 412, a second bit of the control signal 298pk may be provided to a gate of the second selection transistor 414, and a third bit of the control signal 298pk may be provided to a gate of the third selection transistor 416. As described below, bits of the control signal 298pk may also be provided to a tuning circuit 420 to adjust a resonating frequency of a tuning circuit 420 (e.g., an LC circuit). The tuning circuit 420 may be coupled to a drain of the first selection transistor 412, to a drain of the second selection transistor 414, and to a drain of the third selection transistor 416.

When the first bit of the control signal 298pk has a logical high voltage level (and the second and third bits of the control signal 298pk have logical low voltage levels), the first selection transistor 412 may activate to pass and amplify signal components of the input RF signal 294pk. Thus, when the first bit of the control signal 298pk has the logical high voltage level, the tuning circuit 420 may be selectively coupled to the first transistor 302 via the first selection transistor 412. The control signal 298pk may also dynamically adjust the inductance and the capacitance of the tuning circuit 420 such that the tuning circuit 420 resonates at a frequency in the first frequency band. Tuning the tuning circuit 420 to the first frequency band may enable the transistors 302, 412 to amplify and pass first signal components (within the first frequency band) of the input RF signal 294pk to generate the output RF signal 296pk having a frequency within the first frequency band.

When the second bit of the control signal 298pk has a logical high voltage level (and the first and third bits of the control signal 298pk have logical low voltage levels), the second selection transistor 414 may activate to pass and amplify signal components of the input RF signal 294pk. Thus, when the second bit of the control signal 298pk has the logical high voltage level, the tuning circuit 420 may be selectively coupled to the second transistor 304 via the second selection transistor 414. The control signal 298pk may also dynamically adjust the inductance and the capacitance of the tuning circuit 420 such that the tuning circuit 420 resonates at a frequency in the second frequency band. Tuning the tuning circuit 420 to the second frequency band may enable the transistors 304, 414 to amplify and pass second signal components (within the second frequency band) of the input RF signal 294pk to generate the output RF signal 296pk having a frequency within the second frequency band.

When the third bit of the control signal 298pk has a logical high voltage level (and the first and second bits of the control signal 298pk have logical low voltage levels), the third selection transistor 416 may activate to pass and amplify signal components of the input RF signal 294pk. Thus, when the third bit of the control signal 298pk has the logical high voltage level, the tuning circuit 420 may be selectively coupled to the third transistor 306 via the third selection transistor 416. The control signal 298pk may also dynamically adjust the inductance and the capacitance of the tuning circuit 420 such that the tuning circuit 420 resonates at a frequency in the third frequency band. Tuning the tuning circuit 420 to the third frequency band may enable the transistors 306, 416 to amplify and pass third signal components (within the third frequency band) of the input RF signal 294pk to generate the output RF signal 296pk having a frequency within the third frequency band.

The amplification circuitry 300 of FIG. 4 may reduce die area consumption by coupling each transistor 302-306 (e.g., each LNA branch) to different tapping points of the shared degeneration inductor 310 as opposed coupling an independent degeneration inductor to each branch. For example, the first transistor 302 may use “turns” of the second degeneration inductor 314 and the third degeneration inductor 316 to generate a relatively large degeneration inductance to reduce the size (e.g., the number of turns) that would otherwise be necessary if an independent degeneration inductor was coupled to the source of the first transistor 302.

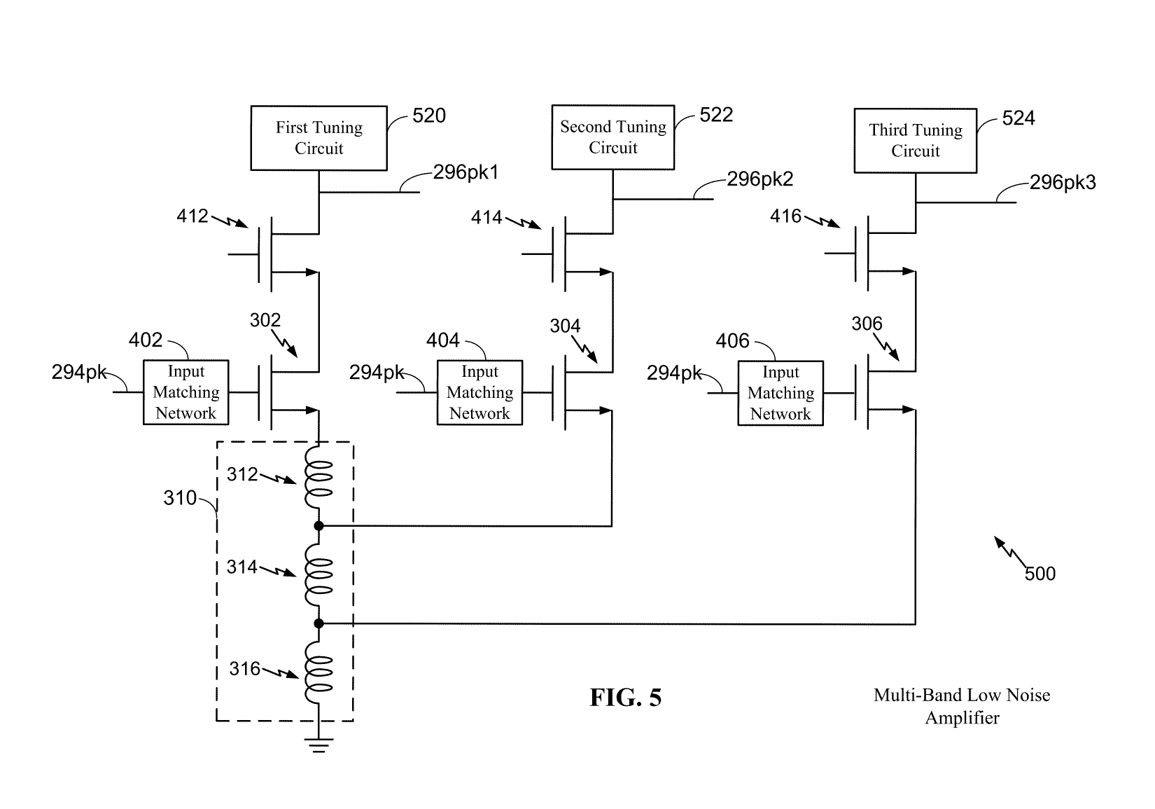

Referring to FIG. 5, a diagram of an exemplary embodiment of a multi-band low noise amplifier having a shared degeneration inductor is shown. For example, FIG. 5 illustrates another exemplary embodiment of amplification circuitry 500 that may be integrated into the LNA 240pk of FIG. 2. The amplification circuitry 500 may correspond to a multi-band low noise amplifier.

A first tuning circuit 520 may be coupled to the drain of the first selection transistor 412, a second tuning circuit 522 may be coupled to the drain of the second selection transistor 414, and a third tuning circuit 524 may be coupled to the drain of the third selection transistor 416. The first tuning circuit 520 may resonate at a frequency within the first frequency band (e.g., the low frequency band), the second tuning circuit 522 may resonate at a frequency within the second frequency band (e.g., the mid-range frequency band), and the third tuning circuit 524 may resonate at a frequency within the third frequency band (e.g., the high frequency band).

The first selection transistor 412 may selectively couple the first tuning circuit 520 to the first transistor 302, the second selection transistor 414 may selectively couple the second tuning circuit 522 to the second transistor 304, and the third selection transistor 416 may selectively couple the third tuning circuit 524 to the third transistor 306. The selection transistors 412, 414, 416 may selectively couple the tuning circuits 520, 522, 524 to the transistors 302, 304, 306, respectively, based on control signals (not shown) provided to the gates of the selection transistors 412, 414, 416 (in a substantially similar manner as described with respect to FIG. 4). As a non-limiting example, if a control signal provided to the gate of the first selection transistor 412 has a logical high voltage level, the first selection transistor 412 may couple the first tuning circuit 520 to the first transistor 302. Similar operations may be performed with respect to the second selection transistor 414 and with respect to the third selection transistor 416.

Other components of the amplification circuitry 500 may have a substantially similar architecture as the amplification circuitry 300 of FIG. 4. For example, components having identical numerical indicators in FIGS. 4 and 5 may operate in a substantially similar manner.

During operation, each selection transistor 412-416 may be simultaneously enabled such that the first transistor 302, the second transistor 304, and the third transistor 306 simultaneously amplify components of the input RF signal 294pk. For example, the first transistor 302 may amplify first signal components of the input RF signal 294pk to generate a first output RF signal 296pk1 based on the resonating frequency of the first tuning circuit 520, the second transistor 304 may simultaneously amplify second signal components of the input RF signal 294pk to generate a second output RF signal 296pk2 based on the resonating frequency of the second tuning circuit 522, and the third transistor 306 may simultaneously amplify third signal components of the input RF signal 294pk to generate a third output RF signal 296pk3 based on the resonating frequency of the third tuning circuit 524. The first output RF signal 296pk1 may have a frequency within the first frequency band, the second output RF signal 296pk2 may have a frequency within the second frequency band, and the third output RF signal 296pk3 may have a frequency within the third frequency band. Each output RF signal 296pk1, 296pk2, 296pk3 may correspond to a portion of the output RF signal 296pk of FIG. 2. For example, the output RF signals 296pk1, 296pk2, 296pk3 may be provided to the receive circuits 242pk of FIG. 2.

The amplification circuitry 500 of FIG. 5 may reduce die area consumption by coupling each transistor 302-306 (e.g., each LNA branch) to different tapping points of the shared degeneration inductor 310 as opposed coupling an independent degeneration inductor to each branch. The amplification circuitry 500 of FIG. 5 may also enable concurrent operation in multiple frequency bands.

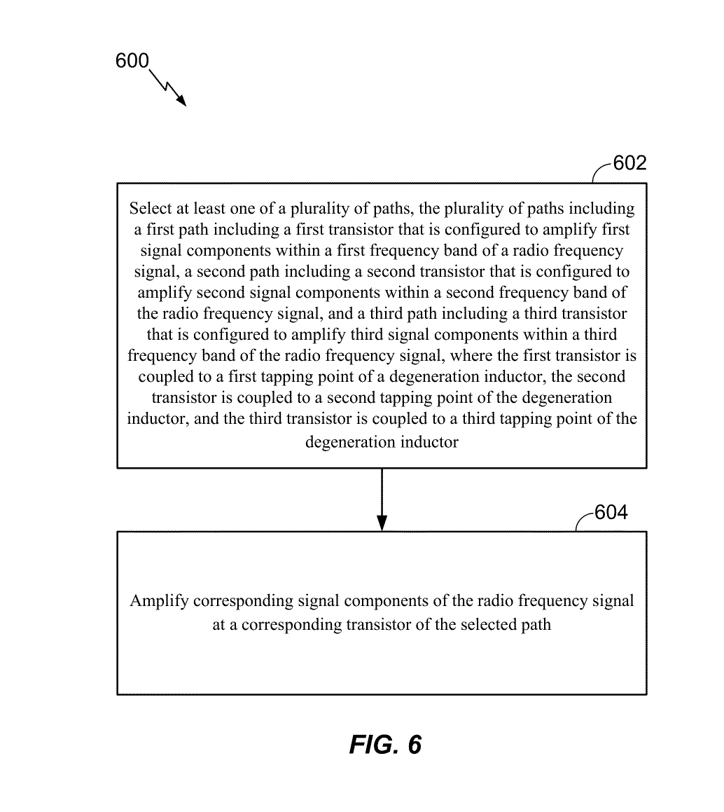

Referring to FIG. 6, a flowchart illustrates an exemplary embodiment of a method 600 of operating a multi-band low noise amplifier with a shared degeneration inductor is shown. In an exemplary embodiment, the method 600 may be performed using the wireless device 110 of FIGS. 1-2, the multi-band low noise amplifier 240pk of FIG. 2, the amplification circuitry 300 of FIGS. 2-4, the amplification circuitry 500 of FIG. 5, or any combination thereof.

The method 600 includes selecting at least one of a plurality of paths, at 602. For example, referring to FIG. 3, the plurality of paths may include the first path, the second path, and the third path. The first path may include the first transistor 302 that is configured to amplify first signal components within the first frequency band of the input RF signal 294pk, the second path may include the second transistor 304 that is configured to amplify second signal components within the second frequency band of the input RF signal 294pk, and the third path may include the third transistor 306 that is configured to amplify third signal components within the third frequency band of the input RF signal 294pk. The first transistor 302 is coupled to the first tapping point of the shared degeneration inductor 310, the second transistor 304 is coupled to the second tapping point of the shared degeneration inductor 310, and the third transistor 306 is coupled to the third tapping point of the shared degeneration inductor 310.

Corresponding signal components of a radio frequency signal may be amplified at a corresponding transistor of the selected path, at 604. For example, referring to FIG. 4, when the first bit of the control signal 298pk has a logical high voltage level (and the second and third bits of the control signal 298pk have logical low voltage levels), the first selection transistor 412 may activate to pass and amplify signal components of the input RF signal 294pk. The control signal 298pk may also dynamically adjust the inductance and the capacitance of the tuning circuit 420 such that the tuning circuit 420 resonates at a frequency in the first frequency band. Tuning the tuning circuit 420 to the first frequency band may enable the first transistor 302 and the first selection transistor 412 to amplify and pass first signal components (within the first frequency band) of the input RF signal 294pk to generate the output RF signal 296pk having a frequency within the first frequency band. Thus, the first transistor 302 of the first path (e.g., the corresponding transistor of the selected path) may amplify first signal components of the input RF signal 294pk.

As another example, when the second bit of the control signal 298pk has a logical high voltage level (and the first and third bits of the control signal 298pk have logical low voltage levels), the second selection transistor 414 may activate to pass and amplify signal components of the input RF signal 294pk. The control signal 298pk may also dynamically adjust the inductance and the capacitance of the tuning circuit 420 such that the tuning circuit 420 resonates at a frequency in the second frequency band. Tuning the tuning circuit 420 to the second frequency band may enable the second transistor 304 and the second selection transistor 414 to amplify and pass second signal components (within the second frequency band) of the input RF signal 294pk to generate the output RF signal 296pk having a frequency within the second frequency band. Thus, the second transistor 304 of the second path (e.g., the corresponding transistor of the selected path) may amplify second signal components of the input RF signal 294pk.

As a further example, when the third bit of the control signal 298pk has a logical high voltage level (and the first and second bits of the control signal 298pk have logical low voltage levels), the third selection transistor 416 may activate to pass and amplify signal components of the input RF signal 294pk. The control signal 298pk may also dynamically adjust the inductance and the capacitance of the tuning circuit 420 such that the tuning circuit 420 resonates at a frequency in the third frequency band. Tuning the tuning circuit 420 to the third frequency band may enable the third transistor 306 and the third selection transistor 416 to amplify and pass third signal components (within the third frequency band) of the input RF signal 294pk to generate the output RF signal 296pk having a frequency within the third frequency band. Thus, the third transistor 306 of the third path (e.g., the corresponding transistor of the selected path) may amplify third signal components of the input RF signal 294pk.

As another example, as described with respect to FIG. 5, multiple paths may be selected to enable concurrent operation in multiple frequency bands. For example, each selection transistor 412-416 may be simultaneously enabled such that the first transistor 302, the second transistor 304, and the third transistor 306 simultaneously amplify components of the input RF signal 294pk. For example, the first transistor 302 may amplify first signal components of the input RF signal 294pk to generate the first output RF signal 296pk1 based on the resonating frequency of the first tuning circuit 520, the second transistor 304 may simultaneously amplify second signal components of the input RF signal 294pk to generate the second output RF signal 296pk2 based on the resonating frequency of the second tuning circuit 522, and the third transistor 306 may simultaneously amplify third signal components of the input RF signal 294pk to generate the third output RF signal 296pk3 based on the resonating frequency of the third tuning circuit 524.

The method 600 of FIG. 6 may reduce die area consumption by coupling each transistor 302-306 (e.g., each LNA branch) to different tapping points of the shared degeneration inductor 310 as opposed to coupling an independent degeneration inductor to each branch. For example, the first transistor 302 may use “turns” of the second degeneration inductor 314 and the third degeneration inductor 316 to generate a relatively large degeneration inductance rather than using an independent degeneration inductor coupled to the source of the first transistor 302. Using the second degeneration inductor 314 reduces die area as compared to using an independent inductor coupled to the source of the first transistor 302. In a similar manner, the second transistor 304 may use turns of the third degeneration inductor 316 to generate a “mid-range” inductance to reduce the die area that would otherwise be necessary if an independent inductor was coupled to the source of the second transistor 304.

In conjunction with the described embodiments, an apparatus includes means for amplifying first signal components within a first frequency band of a radio frequency signal. For example, the means for amplifying the first signal components may include the first transistor 302 of FIGS. 3-5, one or more other devices, circuits, or any combination thereof.

The apparatus may also include means for amplifying second signal components within a second frequency band of the radio frequency signal. For example, the means for amplifying the second signal components may include the second transistor 304 of FIGS. 3-5, one or more other devices, circuits, or any combination thereof.

The apparatus may also include means for amplifying third signal components within a third frequency band of the radio frequency signal. For example, the means for amplifying the third signal components may include the third transistor 306 of FIGS. 3-5, one or more other devices, circuits, or any combination thereof.

The apparatus may also include means for generating an inductance having a first tapping point, a second tapping point, and a third tapping point. The first tapping point may be coupled to the means for amplifying the first signal components, the second tapping point may be coupled to the means for amplifying the second signal components, and the third tapping point may be coupled to the means for amplifying the third signal components. For example, the means for generating the inductance may include the shared degeneration inductor 310 of FIGS. 3-5, one or more other devices, circuits, or any combination thereof The means for amplifying the first signal components, the means for amplifying the second signal components, the means for amplifying the third signal components, and the means for generating the inductance may be included in a multi-band low noise amplifier.

Those of skill would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal In the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

What is claimed is:

1. An apparatus comprising:
a first transistor configured to amplify first signal components within a first frequency band of a radio frequency signal;
a second transistor configured to amplify second signal components within a second frequency band of the radio frequency signal;
a third transistor configured to amplify third signal components within a third frequency band of the radio frequency signal; and
a degeneration inductor having a first tapping point, a second tapping point, and a third tapping point, the first tapping point coupled to the first transistor, the second tapping point coupled to the second transistor, and the third tapping point coupled to the third transistor.

2. The apparatus of claim 1, wherein the first tapping point is coupled to a source of the first transistor, wherein the second tapping point is coupled to a source of the second transistor, and wherein the third tapping point is coupled to a source of the third transistor.

3. The apparatus of claim 1, wherein a center frequency of the second frequency band is greater than a center frequency of the first frequency band.

4. The apparatus of claim 3, wherein a center frequency of the third frequency band is greater than the center frequency of the second frequency band.

5. The apparatus of claim 1, wherein the first frequency band is a low frequency band, wherein the second frequency band is a mid-range frequency band, and wherein the third frequency band is a high frequency band.

6. The apparatus of claim 1, further comprising a multi-band low noise amplifier, wherein the first transistor, the second transistor, the third transistor, and the degeneration inductor are included in the multi-band low noise amplifier.

7. The apparatus of claim 6, wherein die area consumption of the multi-band low noise amplifier is reduced by coupling the first transistor to the first tapping point and coupling the second transistor to the second tapping point, as compared to coupling the second transistor to a separate inductor.

8. The apparatus of claim 7, wherein die area consumption of the multi-band low noise amplifier is further reduced by coupling the third transistor to the third tapping point, as compared to coupling the third transistor to another separate inductor.

9. The apparatus of claim 6, wherein a first path of the multi-band low noise amplifier includes the first transistor and the degeneration inductor.

10. The apparatus of claim 9, wherein a second path of the multi-band low noise amplifier includes the second transistor and a portion of the degeneration inductor.

11. The apparatus of claim 1, further comprising a tuning circuit selectively coupled to the first transistor, to the second transistor, and to the third transistor.

12. The apparatus of claim 1, further comprising:
a first tuning circuit selectively coupled to the first transistor, wherein the first tuning circuit resonates at a frequency within the first frequency band;
a second tuning circuit selectively coupled to the second transistor, wherein the second tuning circuit resonates at a frequency within the second frequency band; and
a third tuning circuit selectively coupled to the third transistor, wherein the third tuning circuit resonates at a frequency within the third frequency band.

13. The apparatus of claim 12, wherein the first transistor, the second transistor, and the third transistor are configured to concurrently amplify components of the radio frequency signal.

14. An apparatus comprising:
means for amplifying first signal components within a first frequency band of a radio frequency signal;
means for amplifying second signal components within a second frequency band of the radio frequency signal;
means for amplifying third signal components within a third frequency band of the radio frequency signal; and
means for generating an inductance having a first tapping point, a second tapping point, and a third tapping point, the first tapping point coupled to the means for amplifying the first signal components, the second tapping point coupled to the means for amplifying the second signal components, and the third tapping point coupled to the means for amplifying the third signal components.

15. The apparatus of claim 14, further comprising means for tuning the radio frequency signal.

16. The apparatus of claim 14, further comprising a multi-band low noise amplifier, wherein the means for amplifying the first signal components, the means for amplifying the second signal components, the means for amplifying the third signal components, and the means for generating the inductance are included in the multi-band low noise amplifier.

17. The apparatus of claim 14, wherein a center frequency of the second frequency band is greater than a center frequency of the first frequency band, and wherein a center frequency of the third frequency band is greater than the center frequency of the second frequency band.

18. The apparatus of claim 14, wherein the first frequency band is a low frequency band, wherein the second frequency band is a mid-range frequency band, and wherein the third frequency band is a high frequency band.

19. A method comprising:
selecting at least one of a plurality of paths, the plurality of paths including:
a first path including a first transistor that is configured to amplify first signal components within a first frequency band of a radio frequency signal, the first transistor coupled to a first tapping point of a degeneration inductor;
a second path including a second transistor that is configured to amplify second signal components within a second frequency band of the radio frequency signal, the second transistor coupled to a second tapping point of the degeneration inductor; and
a third path including a third transistor that is configured to amplify third signal components within a third frequency band of the radio frequency signal, the third transistor coupled to a third tapping point of the degeneration inductor; and
amplifying corresponding signal components of the radio frequency signal at a corresponding transistor of the selected path.

20. The method of claim 19, wherein selecting the at least one of the plurality of paths includes selecting the first path and the second path, and further comprising amplifying the first signal at the first transistor and amplifying the second signal components at the second transistor.
